(19) United States
(12) Patent Application Publication
(10) Pub. No.: US 2005/0239269 A1
(43) Pub. Date: Oct. 27, 2005

(54) Method for releasing stress of embedded chip and chip embedded structure

(75) Inventors: Chu-Chin Hu, Hsin-chu (TW); Chung-Cheng Lien, Hsin-chu (TW); Chi-Ming Chen, Hsin-chu (TW); Sheng-Hsiang Yang, Hsin-chu (TW); Meng-Da Chou, Hsin-chu (TW)

Correspondence Address: Mr. William F. Nixon;SQUIRE SANDERS & DEMPSEY LLP, 14th Floor, 8000 Towers Crescent Drive, Tysons Corner, VA, 22182-2700, US

(73) Assignee: Phoenix Precision Technology Corporation

(21) Appl. No.: 10/947,357

(22) Filed: Sep. 23, 2004

(30) Foreign Application Priority Data
Apr. 27, 2004 (TW) 093111685

(51) Int. Cl. H01L 21/301

(52) U.S. Cl. 438/460

(57) ABSTRACT

A method for releasing stress of an embedded chip and a chip embedded structure are proposed. Cutting processes are performed to a semiconductor chip before it is embedded in a circuit board to form cut-way portions at edges of the chip so as to allow stress to be released when the chip is subsequently embedded in the circuit board and a filler material is filled between the chip and the circuit board.

### FIELD OF THE INVENTION

The present invention relates to methods for releasing stress of embedded chips and chip embedded structures, and more particularly, to a method for effectively releasing stress of a semiconductor chip embedded in a circuit board, and a circuit board with the embedded chip.

### BACKGROUND OF THE INVENTION

Owing to the increasing demand for lighter, thinner, more compact and complicated electronic devices, semiconductor structures have been gradually developed towards chip-scale structures. Thus, how to efficiently arrange semiconductor chips with high density of circuitry on a gradually reduced area of a chip carrier has become one of the most important problems in the semiconductor carrier industry.

Moreover, for normal manufacturing processes of semiconductor devices, firstly chip carrier manufacturers produce chip carriers suitable for the semiconductor devices such as various types of circuit boards or lead frames. Then, semiconductor packaging manufacturers subject the chip carriers to die bonding, wire bonding, molding, and ball implanting processes so as to fabricate the semiconductor devices with electronic functionality desired by clients. The above manufacturing processes involve a number of different manufacturers, including the chip carrier manufacturers and semiconductor packaging manufacturers, thereby making the manufacturing processes complicated in practice and not easy to achieve interface integration. In case the clients wish to modify the product design, the changes and integration involved are even more complicated, not meeting the requirements of flexibility in change and economical benefit.

Therefore, how to efficiently integrate the various manufacturing interfaces for semiconductor devices has become an imperative problem to be addressed.

In order to address this problem, the applicant has developed a circuit board structure suitable for being integrated with semiconductor chips so as to solve the interface integration problem during the manufacturing processes of semiconductor devices. However, when the chip is embedded in the circuit board, stress tends to be concentrated on edges of the chip, causing the circuit board bulged at positions corresponding to the edges of the chip in a pressing process, and thus adversely affecting the reliability of subsequent manufacturing processes.

### SUMMARY OF THE INVENTION

In light of the problems and drawbacks in the prior art, a primary objective of the present invention is to provide a method for releasing stress of an embedded chip and a chip embedded structure, so as to reduce stress concentrated on edges of the chip when the chip is embedded in a circuit board.

In order to achieve the above and other objectives, the present invention proposes a method for releasing stress of an embedded chip, comprising the steps of: providing a wafer comprising a plurality of semiconductor chips, the wafer having an active surface and a non-active surface opposite to the active surface; performing a semi-cutting process at boundaries between the adjacent chips on the active surface of the wafer to form a plurality of grooves; and performing a full-cutting process at the grooves to separate the plurality of chips from each other, such that each of the separated chips is formed with cut-away portions at edges of its active surface. When such a chip is subsequently embedded in a circuit board and a filler material is filled between the chip and the circuit board, stress concentrated on the chip can be reduced by provision of the cut-away portions.

In another preferred embodiment of the present invention, the method for releasing stress of an embedded chip comprises the steps of: providing a wafer comprising a plurality of semiconductor chips, the wafer having an active surface and a non-active surface opposite to the active surface; performing a semi-cutting process at boundaries between the adjacent chips on the active surface of the wafer to form a plurality of grooves; and performing a full-cutting process on the non-active surface of the wafer to separate the plurality of chips from each other in a manner that each of the separated chips is formed with cut-away portions at edges of its active and non-active surfaces to reduce stress concentrated on the chip when the chip is subsequently embedded in a circuit board.

By the foregoing methods, the present invention also discloses a chip embedded structure comprising: a support board having at least one opening; and at least one semiconductor chip received in the opening, wherein the chip is formed with cut-away portions at its edges to allow stress concentrated on the chip to be reduced when a filler material is filled between the chip and the opening of the support board.

Therefore, the method of releasing stress of an embedded chip according to the present invention is to perform cutting process at the edges of the chip to form cut-away portions prior to embedding the chip in a circuit board, such that when the chip is subsequently embedded in the circuit board and a filler material is filled between the chip and the circuit board, stress concentrated on the edges of the chip can be reduced.

### BRIEF DESCRIPTION OF THE DRAWINGS

The invention can be more fully understood by reading the following detailed description of the preferred embodiments, with reference made to the accompanying drawings, wherein:

FIGS. 1A to 1E are schematic diagrams showing the procedural steps of a method for releasing stress of an embedded chip according to a first preferred embodiment of the present invention; and

FIGS. 2A to 2E are schematic diagrams showing the procedural steps of a method for releasing stress of an embedded chip according to a second preferred embodiment of the present invention.

### DETAILED DESCRIPTION OF THE PREFFERED EMBODIMENTS

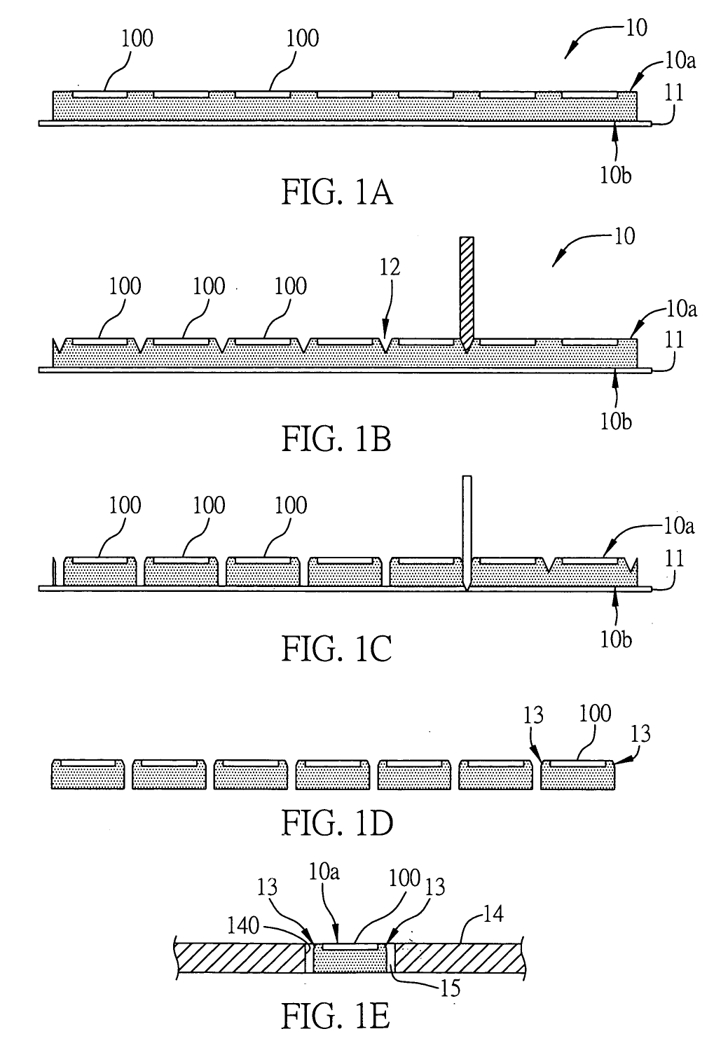

FIGS. 1A to 1E show the procedural steps of a method for releasing stress of an embedded chip according to a first preferred embodiment of the present invention.

Referring to FIG. 1A, a semiconductor wafer 10 is provided having an active surface 10a and a non-active surface 10b opposite to the active surface 10a. The wafer 10 comprises a plurality of semiconductor chips 100, and an adhesive layer 11 is disposed on the non-active surface 10b of the wafer 10 to carry the plurality of chips 100 when being separated at a later stage.

Referring to FIG. 1B, a semi-cutting process is performed at boundaries between the adjacent chips 100 on the active surface 10a of the wafer 10. The semi-cutting process can employ a V-shaped cutting tool to form a plurality of V-shaped grooves 12 at the boundaries between the adjacent chips 100.

Referring to FIG. 1C, a wafer-cutting machine is utilized to perform a full-cutting process at the V-shaped grooves 12 to separate the plurality of chips 100 from each other. Then referring to FIG. 1D, the adhesive layer 11 is removed. As a result, the separated chips 100 each is formed with cut-away portions 13 (such as beveled surfaces) at edges of its active surface. Subsequently referring to FIG. 1E, the chip 100 with the cut-away portions 13 can be embedded in a circuit board 14, and stress concentrated on the edges of the chip 100 can be reduced when a filler material 15 is filled between the chip 100 and the circuit board 14 by provision of the cut-away portions 13.

Further referring to FIG. 1E, the present invention also discloses a chip embedded structure comprising: a circuit board 14 having at least one opening 140; and at least one semiconductor chip 100 received in the opening 140, wherein the chip 100 is formed with cut-away portions 13 at edges of its active surface 10a, such that when a filler material 15 is filled between the chip 100 and the circuit board 14 for following process to form the conductive traces to connect to chip (not shown in the figure.), stress concentrated on the chip 100 can be reduced. Moreover, such a chip having the cut-away portions is not limited to the use with a circuit board, but can also be embedded in a normal support board such as a metal or insulating board.

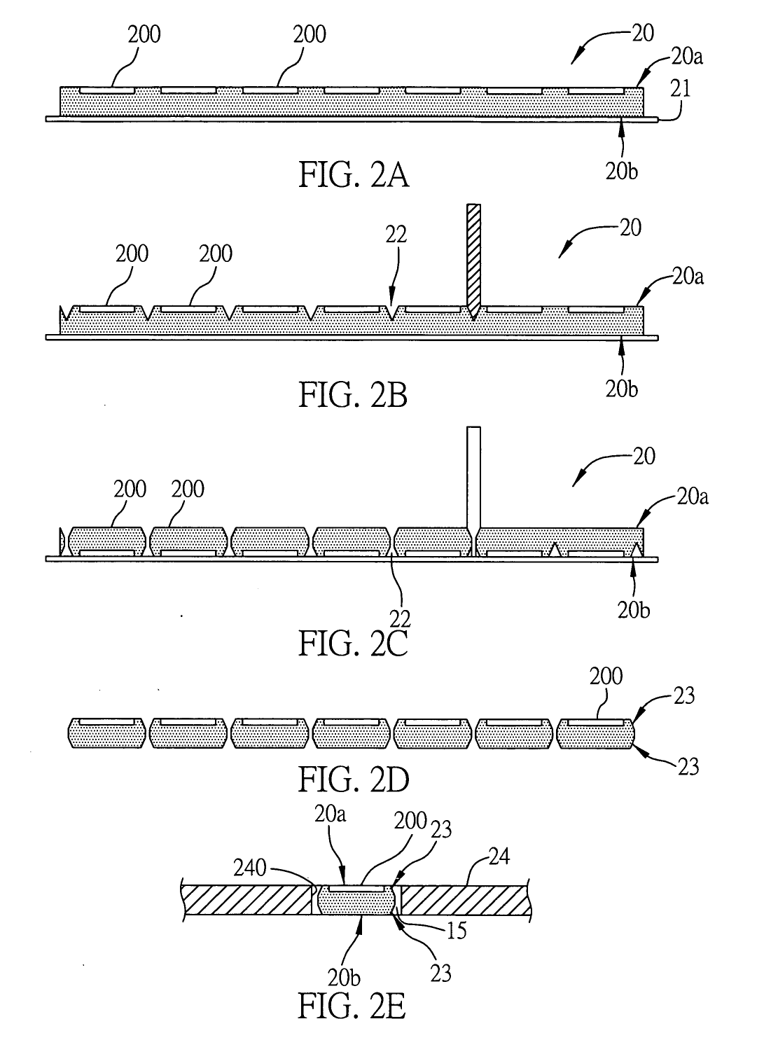

FIGS. 2A to 2E show the procedural steps of a method for releasing stress of an embedded chip according to a second preferred embodiment of the present invention. The procedural steps of the method in the second embodiment are similar to those of the method in the above first embodiment, with the main difference in that in the second embodiment, cut-away portions are formed at edges of both an active surface and a non-active surface of the chip.

Referring to FIG. 2A, a semiconductor wafer 20 is provided having an active surface 20a and a non-active surface 20b opposite to the active surface 20a. The wafer 20 comprises a plurality of semiconductor chips 200, and an adhesive layer 21 is disposed on the non-active surface 20b of the wafer 20 to carry the plurality of chips when being separated at a later stage.

Referring to FIG. 2B, a semi-cutting process is performed at boundaries between the adjacent chips 200 on the active surface 20a of the wafer 20. The semi-cutting process can employ a V-shaped cutting tool to form a plurality of V-shaped grooves 22 at the boundaries between the adjacent chips 200.

Referring to FIG. 2C, the wafer 20 is turned upside down, and a full-cutting process is performed to cut the non-active surface 20b of the wafer 20 at locations corresponding to the V-shaped grooves 22 on the active surface 20a of the wafer 20 by an infrared alignment technique, so as to separate the plurality of chips 200 from each other and form cut-away portions 23 at edges of the non-active surface 20b of each of the chips 200. Next referring to FIG. 2D, the adhesive layer 21 is removed, such that the separate chips 200 each is formed with the cut-away portions 23 at the edges of its active and non-active surfaces 20a, 20b. Subsequently referring to FIG. 2E, the chip 200 with the cut-away portions 23 can be embedded in a circuit board 24 for following process to form the conductive traces to connect to chip (not shown in the figure.), and stress concentrated on the edges of the chip 200 can be reduced when a filler material 25 is filled between the chip 200 and the circuit board 24 by provision of the cut-away portions 23.

Further referring to FIG. 2E, the present invention also discloses a chip embedded structure comprising: a circuit board 24 having at least one opening 240; and at least one semiconductor chip 200 received in the opening 240, wherein the chip 200 is formed with cut-away portions 23 at edges of its active and non-active surfaces 20a, 20b, such that when a filler material 25 is filled between the chip 200 and the circuit board 24, stress concentrated on the chip 200 can be reduced. Moreover, such a chip having the cut-away portions is not limited to the use with a circuit board, but can also be embedded in a normal support board such as a metal or insulating board.

Therefore, the method of releasing stress of an embedded chip according to the present invention is to perform cutting process at the edges of the chip to form cut-away portions prior to embedding the chip in a circuit board, such that when the chip is subsequently embedded in the circuit board and a filler material is filled between the chip and the circuit board, stress concentrated on the edges of the chip can be reduced.

The present invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A method for releasing stress of an embedded chip, comprising the steps of:
providing a wafer comprising a plurality of semiconductor chips, the wafer having an active surface and a non-active surface opposite to the active surface;
performing a semi-cutting process at boundaries between the adjacent chips on the active surface of the wafer to form a plurality of grooves; and
performing a full-cutting process at the grooves to separate the plurality of chips from each other, such that each of the separated chips is formed with cut-away portions at edges of its active surface to allow stress concentrated on the chip to be reduced when the chip is embedded in a circuit board.

2. The method as claimed in claim 1, wherein the chip is received in an opening of the circuit board, and a filler material is filled between the chip and the circuit board.

3. The method as claimed in claim 1, wherein an adhesive layer is formed on the non-active surface of the wafer for carrying the separated chips.

4. The method as claimed in claim 1, wherein the semi-cutting process uses a V-shaped cutting tool such that the grooves formed at the boundaries between the adjacent chips are V-shaped.

5. The method as claimed in claim 4, wherein the full-cutting process uses a wafer-sawing machine to cut the wafer at the V-shaped grooves to separate apart the plurality of chips.

6. A method for releasing stress of an embedded chip, comprising the steps of:
providing a wafer comprising a plurality of semiconductor chips, the wafer having an active surface and a non-active surface opposite to the active surface;
performing a semi-cutting process at boundaries between the adjacent chips on the active surface of the wafer to form a plurality of grooves; and
performing a full-cutting process on the non-active surface of the wafer to separate the plurality of chips from each other in a manner that each of the separated chips is formed with cut-away portions at edges of its active and non-active surfaces to allow stress concentrated on the chip to be reduced when the chip is embedded in a circuit board.

7. The method as claimed in claim 6, wherein the chip is received in an opening of the circuit board, and a filler material is filled between the chip and the circuit board.

8. The method as claimed in claim 6, wherein an adhesive layer is formed on the non-active surface of the wafer for carrying the separated chips.

9. The method as claimed in claim 6, wherein the semi-cutting process uses a V-shaped cutting tool such that the grooves formed at the boundaries between the adjacent chips on the active surface of the wafer are V-shaped.

10. The method as claimed in claim 9, wherein the full-cutting process uses an infrared alignment technique to cut the non-active surface of the wafer at locations corresponding to the V-shaped grooves on the active surface of the wafer, so as to separate apart the plurality of chips and form the cut-away portions at the edges of the non-active surface of the chips.

11. A chip embedded structure, comprising:
a support board having at least one opening; and
at least one semiconductor chip received in the opening, wherein the chip is formed with cut-away portions at its edges to allow stress concentrated on the chip to be reduced when a filler material is filled between the chip and the support board.

12. The chip embedded structure as claimed in claim 11, wherein the support board is a circuit board.

13. The chip embedded structure as claimed in claim 11, wherein the support board is a metal board.

14. The chip embedded structure as claimed in claim 11, wherein the support board is an insulating board.

15. The chip embedded structure as claimed in claim 11, wherein the cut-away portions are formed at the edges of an active surface of the chip.

16. The chip embedded structure as claimed in claim 11, wherein the cut-away portions are formed at the edges of an active surface and a non-active surface of the chip.
